(19) United States
(12) Patent Application Publication
(10) Pub. No.: US 2006/0081184 A1
(43) Pub. Date: Apr. 20, 2006

(54) Evaporation mask with high precision deposition pattern

(76) Inventor: Te Lang Yeh, Hsinchu (TW)

Correspondence Address: Yeh, Te Lang, 235 Chung-Ho, Box 8-24, Taipei, TW

(21) Appl. No.: 10/967,843

(22) Filed: Oct. 19, 2004

(51) Int. Cl. C23C 16/00

(52) U.S. Cl. 118/720

(57) ABSTRACT

An evaporation mask comprises a substrate having a deposition surface; an evaporation mask installed below the deposition surface of the substrate; the thermal expansion coefficient of the evaporation mask being not greater than that of the substrate; a plurality of rectangular mask working units being arranged on the substrate; for each mask working unit, the substrate being concaved to have a concave portion; and a plurality of evaporation layer; each evaporation layer being located within a respective concave portion; wherein each evaporation layer is engraved with penetrating recesses with a predetermined pattern as deposition pattern; a periphery of the mask working unit is formed with a thick rib portion. A cross section of the hole has a shape identical to “/ \”, “> <”, “ [symbol] [symbol] ”, “\ /”, “< >”, or “ [symbol] [symbol] ”. A high precision deposition pattern is acquired on a deposited working substrate.

### FIELD OF THE INVENTION

The present invention relates to evaporation deposition, and particularly to an evaporation mask with high precision deposition pattern.

### BACKGROUND OF THE INVENTION

Evaporation deposition is widely used in the manufacturing process of electronic devices, for example, self-emitting, wide visual angle, high color contrast, and high resolution organic light emitting display (OLED) uses evaporation deposition in the manufacturing process of electroluminescent elements (EL elements). In the manufacturing of EL, in general, a substrate (such as a glass substrate) is mounted with transparent anodes, such as indium tin oxide (ITO), and cathodes, such as lower power function metals, for example, Al, Mg, or Ca. A layer of organic light emitting layer is deposited between the anode and cathode. In this process, the metal electrodes and organic light emitting layer are made of evaporation deposition process. In the evaporation process, an evaporation mask is formed with holed pattern for confining deposition areas so as to deposit desired patterns on the substrate.

In general, evaporation deposition is performed on a vacuum chamber. A bottom surface of the substrate is made as a deposition surface. An evaporation mask is arranged between the deposition surface of the substrate and an evaporation source. In the evaporation deposition process, the evaporation source is heated so that the evaporation material evaporates. The material passes through the holed pattern to be adhered upon the deposition surface.

In the evaporation deposition, to form a precise deposition pattern, other than forming evaporation holes corresponding to a predetermined pattern, since the evaporation mask is arranged to be near the evaporation source and the evaporated material will flow toward the pattern. Thereby the evaporation mask for shielding the evaporation object will receive the heat of the evaporated material. Thereby the evaporation mask must be heat-tolerant.

Current known evaporation masks are metal masks made of Nickel. In the evaporation deposition process, due the thermal deformation of the Nickel mask, the positions of the predetermined evaporation holes will shift so that the pattern formed is deformed. Especially, in some elements needing a high precision pattern (such as organic light emitting display of very small area), the thermal deformation of the mask will induce the organic layer to shift. However this is an important problem. Besides since large size of display is more and more popular, and a larger mother substrate is used to form a plurality of sub-display panels, wide evaporation areas are necessary and thus large scale masks are used. When the area of the evaporation mask is larger, the thermal deformation of the mask is enlarged so that the shift of position is also large. Besides since the mask is very thin and the mask is heavy, the metal mask of larger area will be difficult to be adhered to the deposition surface and moreover it easily deforms due to gravitational force. Thereby in installing a thin mask, the webbing and spot welding technology is necessary so that it is very difficult to install the mask to the support frame.

### SUMMARY OF THE INVENTION

Accordingly, the primary object of the present invention is to provide an evaporation mask with high precision deposition pattern, wherein glass or quartz is used to replace metal or metal alloy as a mask in deposition. By the lower thermal expansion coefficients of the glass or quartz, large thermal deformation due to high temperature in the deposition process is avoided so that the positions of the deposition is not shift and thus a high precision deposition pattern will be acquired.

According to the present invention, An evaporation mask has a mask substrate made of material, such as glass, quartz, MgF2 or CaF2, having an expansion coefficient identical to that of an object to be deposited. The mask substrate is arranged with at least one mask working unit arranged as a matrix. The mask working unit has a concave mask layer installed on the mask substrate. The thickness of the layer is about 50 to 500 μm. At least one penetrating recess with a patter corresponding to a predetermined pattern is formed on the mask layer as an evaporation hole. With respect to the thinner mask layer, a periphery of the mask working unit has a thicker rib for enhancing the structure of the mask substrate and preventing the deformation of the mask substrate.

A cross section view of the hole has a shape identical to “/ \”, “> <”, “ [symbol] [symbol] ”, “\ /”, “< >”, or “ [symbol] [symbol] ”. By the high strength and lower expansion coefficient of the evaporation mask, the deformation in the evaporation process is avoided and thus the pattern in the evaporation film is retained. A high precision deposition pattern is acquired on a deposited working substrate.

In the present invention, the evaporation layers 12 of the evaporation mask 1 are interconnected to the rib portions 14 as an integral body. The rib portions 14 have the effect of enhancing the strength so that the evaporation mask 1 can be installed to the supporting unit 3 easily. Moreover, the mask working unit 11 (i.e., the evaporation layer 12) and the rib portions 14 are made of same material so that they have the same thermal expansion coefficient. Therefore, the temperature increment in the evaporation process will not deform the structure due to the overlarge thermal stress between the mask working unit 11 and the support structure so as to reduce the preciseness of the pattern or the mask is destroyed.

In the present invention, the evaporation mask is made of material selected from one of glass, quarts, MgF₂ and CaF₂.

The various objects and advantages of the present invention will be more readily understood from the following detailed description when read in conjunction with the appended drawing.

### BRIEF DESCRIPTION OF THE DRAWINGS

FIG. 1 is a partial cross sectional view about the arrangement of the mask working unit on the deposition surface of the present invention.

FIG. 2 is a schematic cross view showing the arrangement of the evaporation mask below the substrate to be evaporated according to the present invention.

FIG. 3 is a cross sectional view of the W portion of FIG. 2, wherein the deposition pattern is formed on the evaporation layer.

FIG. 4A is a partial enlarged view of the M portion in FIG. 3, wherein one type of the pattern on the pattern surface of the present invention is illustrated.

FIG. 4B is a partial enlarged view of the M portion in FIG. 3, wherein a second type of the pattern on the pattern surface of the present invention is illustrated.

FIG. 4C is a partial enlarged view of the M portion in FIG. 3, wherein a third type of the pattern on the pattern surface of the present invention is illustrated.

FIG. 4D is a partial enlarged view of the M portion in FIG. 3, wherein a fourth type of the pattern on the pattern surface of the present invention is illustrated.

FIG. 4E is a partial enlarged view of the M portion in FIG. 3, wherein a fifth type of the pattern on the pattern surface of the present invention is illustrated.

FIG. 4F is a partial enlarged view of the M portion in FIG. 3, wherein a sixth type of the pattern on the pattern surface of the present invention is illustrated.

FIG. 4G is a partial enlarged view of the M portion in FIG. 3, wherein a seventh type of the pattern on the pattern surface of the present invention is illustrated.

FIG. 4H is a partial enlarged view of the M portion in FIG. 3, wherein a eighth type of the pattern on the pattern surface of the present invention is illustrated.

### DETAILED DESCRIPTION OF THE INVENTION

In order that those skilled in the art can further understand the present invention, a description will be described in the following in details. However, these descriptions and the appended drawings are only used to cause those skilled in the art to understand the objects, features, and characteristics of the present invention, but not to be used to confine the scope and spirit of the present invention defined in the appended claims.

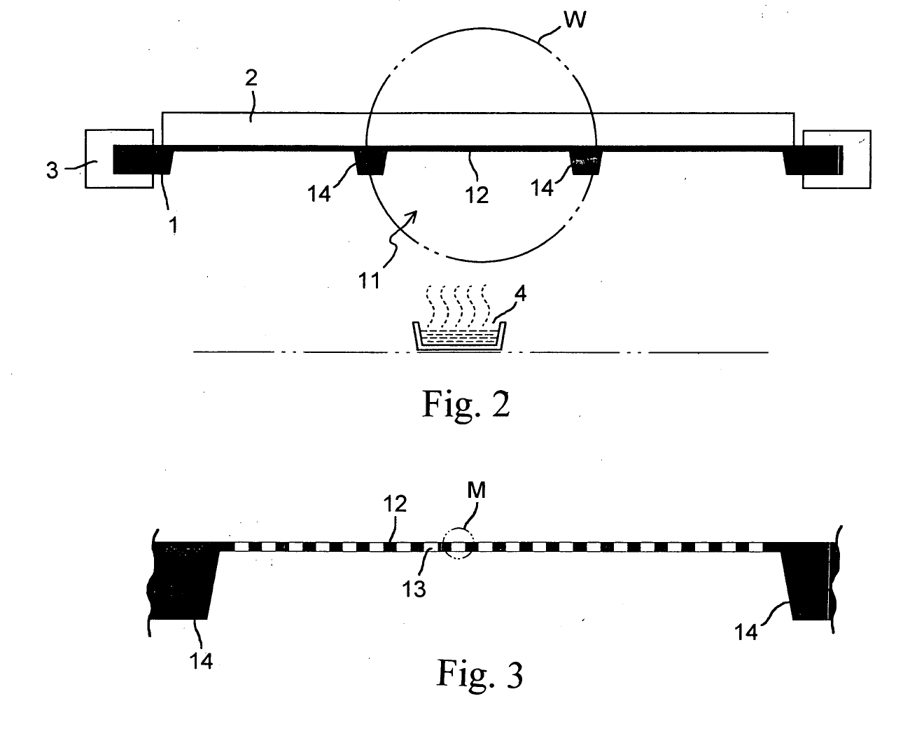

With reference to FIG. 2, the schematic view of evaporation according to the present invention is illustrated.

It is illustrated that a substrate 2 to be deposited is installed in an evaporation chamber of an evaporation device. A deposition surface of the substrate 2 is installed with an evaporation mask 1 below the deposition surface. The evaporation mask 1 is supported by a supporting unit 3. The deposition surface of the substrate 2 almost wholly contacts the evaporation mask 1. An evaporation unit 4 is located below the evaporation mask 1. The evaporation unit 4 is movably along the deposition surface and serves to heat evaporation material so that the material evaporates. Thereby the evaporation unit 4 performs the evaporation work in movement. The vaporized material passes through gaps 13 in the evaporation mask 1 so that the material is adhered to the deposition surface of the substrate 2 so that an evaporation layer with a pattern corresponding to that of the gaps 13 on the evaporation mask 1 is formed on the deposition surface.

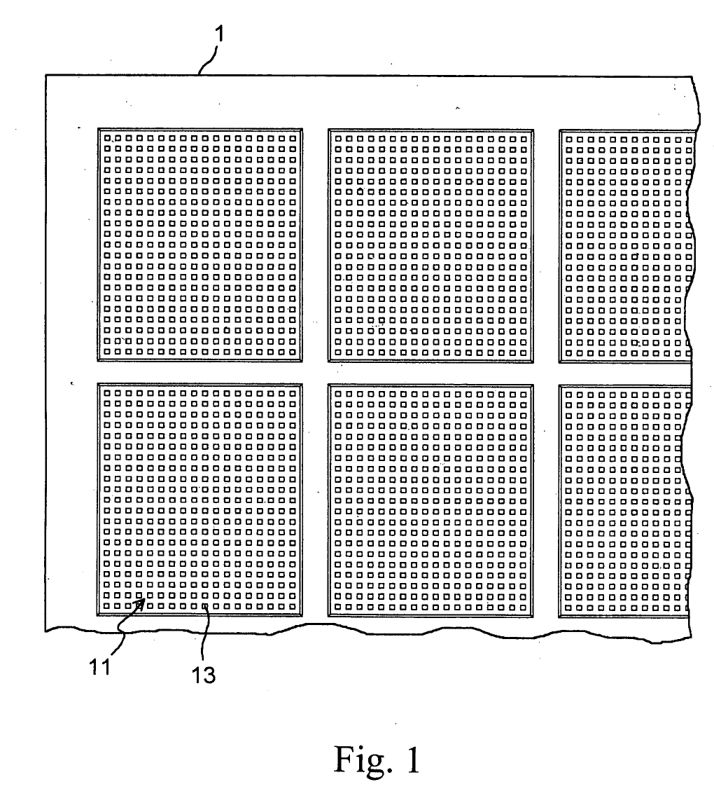

Referring to FIGS. 1, 2, and 3, it is illustrated that a plurality of rectangular mask working units 11 are arranged on the substrate 2. For each mask working unit 11, the substrate 2 is concaved and then an evaporation layer 12 is formed thereon with a thickness of 50 μm to 500 μm. Each evaporation layer 12 is engraved with penetrating recesses with a predetermined pattern as a deposition pattern 13. A periphery of the mask working unit 11 is formed with a thick rib portion 14. All the rib portions 14 at the peripheries of the mask working units 11 are interconnected so as to form with an enhancing supporting frame of the evaporation mask 1 for preventing the deformation of the mask.

In this embodiment, the evaporation mask 1 is made of glass. Glass is a non-metal inorganic material, i.e., inorganic thermal plastic polymer which is formed at temperatures higher than 650° C. After cooling, it is transparent, wear-tolerant, anti-pressured, etc. Glass is non-conductive to heat and electric power and is a brittle amorphous material with a specific weight of 2.64 to 2.5, a linear expansion coefficient of 9˜10×10−6/° C. (˜350° C.), a specific heat of 0.2° C. (0° C.˜50° C.), and a surface tensile strength of about 500 kg/cm². More importantly, the thermal expansion coefficient of glass is lower than metals or alloys which are now used as mask. For example, the thermal expansion coefficient of boron silicic acid glass is about 3×10−6/° C., the thermal expansion coefficient of quartz is as lower as 5×10−7/° C. The current mask material, such as Nickel or Nickel alloy, has thermal expansion coefficients from 30×10−7/° C.˜300×10−7/° C. For example, YEF42 (52 alloy, Fe+42% Ni alloy) has a thermal expansion coefficient of 48×10−7/° C., which is a small one in a current known mask material. For example,, YEF426 (426 alloy, Fe+42%Ni+6%Cr alloy) has a thermal expansion coefficient of 90×10−7/° C. and YEF° C. 52 (52Ni alloy, Fe+52%Ni) has a thermal expansion coefficient of 102×10−7/° C. The thermal expansion coefficient of glass is lower than those known in the prior arts, even only one third of the prior art.

Therefore, the thermal expansion coefficient of the evaporation mask of the present invention is almost identical to that of the substrate 2 (generally, glass) of the evaporation mask element. In the evaporation deposition process, the evaporation mask 1 only has a slight deformation in that, the shifts of evaporation recesses can be neglected. Thereby the pattern can be correctly formed on the glass substrate 2.

Furthermore, from another viewpoint, the thermal expansion of the evaporation mask 1 in the evaporation process will have the same level as that of the glass substrate 2 of the element to be deposited. Thus, the deformation of the evaporation mask 1 is cancelled by the same deformation of the glass substrate 2 of the element to be deposited. Thereby the preciseness of the pattern can be increased.

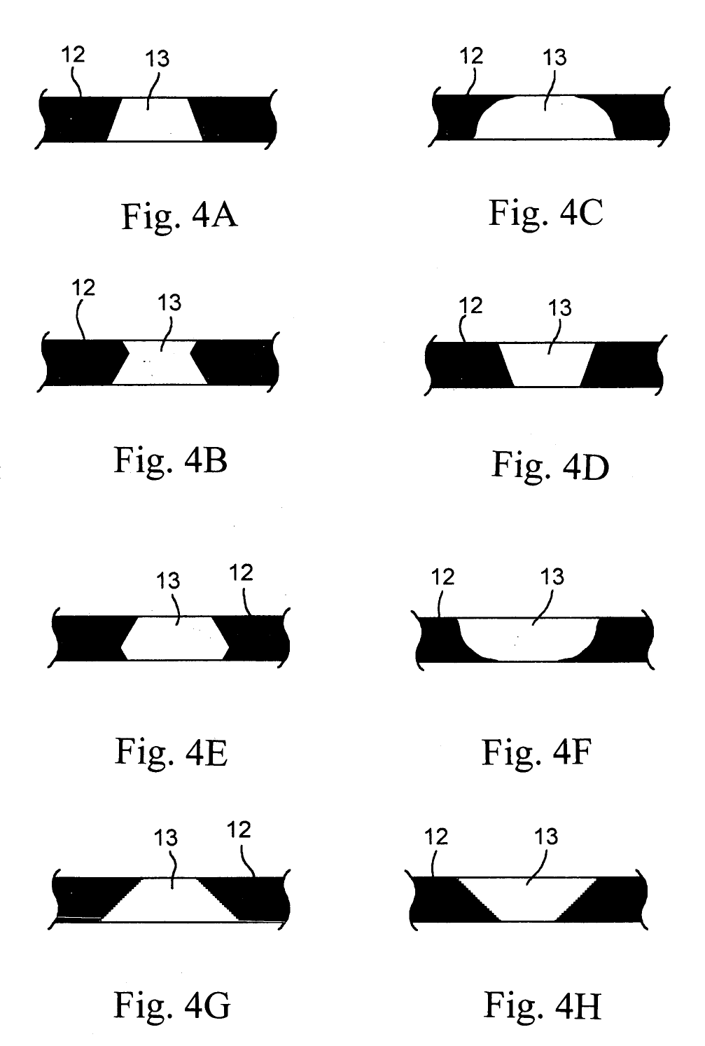

Besides in this embodiment, to make the evaporation layer 12 of the evaporation mask 1 has a predetermined strength for preventing from destroy. In the present invention, since the thickness of the evaporation layer 12 is set to be about 5˜500 μm, comparing with the substrate 2 to be deposited with a thickness of about 0.7 mm, it is thinner, but from the viewpoint of evaporation, when the evaporation layer 12 is thicker, the evaporation material flowing obliquely can not pass through the evaporation recesses of the deposition pattern 13 to be adhered on the deposition surface of the substrate 2 to be deposited. This will induce the evaporation efficiency and evaporation precision to reduce. To avoid this deficiency, in the present invention, the recesses of the deposition pattern 13 is designed to have cross sections of “/ \”, or “> <”, or “ [symbol] [symbol] ”, or “\ /”, or “< >”, or “ [symbol] [symbol] ”, etc. (referring to FIGS. 4A to 4H). Thereby the deposition pattern 13 will receive the evaporation material from inclined paths and then the material is adhered to the deposition surface of the substrate 2 to be evaporated so that the evaporation layer 12 of the evaporation mask 1 has a predetermined thickness (strength). Thereby the problems of low evaporation efficiency and low precision from the thickness of the evaporation layer 12 can be avoided.

In above embodiment, the glass/quartz is used as material of the evaporation layer 12, but other materials with thermal expansion coefficients lower than or near to that of the substrate 2 to be evaporated and having sufficient heat-tolerance can be used in the present invention. All these are within the scope of the present invention. For example, MgF2 with a thermal expansion coefficient 8.48˜13.7×10−6/K, CaF2 with a thermal expansion coefficient 18.85×10−6/K. is permissible.

Furthermore, in the present invention, a thickness of the substrate is between 50 μm to several centimeters.

In the present invention, the evaporation layers 12 of the evaporation mask 1 is interconnected to the rib portions 14 as an integral body. The rib portions 14 have the effect of enhancing the strength so that the evaporation mask 1 can be installed to the supporting unit 3 easily. Moreover, the mask working unit 11 (i.e., the evaporation layer 12) and the rib portions 14 are made of same material so that they have the same thermal expansion coefficient. Therefore, the temperature increment in the evaporation process will not deform the structure due to the overlarge thermal stress between the mask working unit 11 and the support structure so as to reduce the preciseness of the pattern or the mask is destroyed.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. An evaporation mask comprising:
a substrate having a deposition surface;
an evaporation mask installed below the deposition surface of the substrate; the thermal expansion coefficient of the evaporation mask being not greater than that of the substrate;
a plurality of rectangular mask working units being arranged on the substrate; for each mask working unit, the substrate being concaved to have a concave portion; and
a plurality of evaporation layers; each evaporation layer being located within a respective concave portion; wherein each evaporation layer is engraved with penetrating recesses with a predetermined pattern as a deposition pattern; a periphery of each mask working unit being formed with a thick rib portion.

2. The evaporation mask as claimed in claim 1, wherein the evaporation mask is made of material selected from one of glass and quartz.

3. The evaporation mask as claimed in claim 1, wherein the evaporation layer is made of material selected from one of MgF₂ and CaF₂ .

4. The evaporation mask as claimed in claim 1, wherein a thickness of the substrate is between 50 μm to several centimeters.

5. The evaporation mask as claimed in claim 1, wherein a thickness of the evaporation layer is between 50 μm to 500 μm.

6. The evaporation mask as claimed in claim 1, wherein the deposition pattern has gaps of “/ \” shape.

7. The evaporation mask as claimed in claim 1, wherein the deposition pattern has gaps of “> <” shape.

8. The evaporation mask as claimed in claim 1, wherein the deposition pattern has gaps of “ [symbol] [symbol] ” shape.

9. The evaporation mask as claimed in claim 1, wherein the deposition pattern has gaps of “\ /” shape.

10. The evaporation mask as claimed in claim 1, wherein the deposition pattern has gaps of “< >” shape.

12. The evaporation mask as claimed in claim 1, wherein the deposition pattern has gaps of “ [symbol] [symbol] ”shape.

13. The evaporation mask as claimed in claim 1, wherein the deposition pattern is a saw tooth pattern.

14. The evaporation mask as claimed in claim 1, wherein all the rib portions at the peripheries of the mask working units are interconnected so as to form with an enhancing supporting frame of the evaporation mask for preventing the deformation of the mask.

15. The evaporation mask as claimed in claim 1, wherein all the rib portions are spaced equally so as to form a matrix like pattern.
